(19) United States
(12) Patent Application Publication
(10) Pub. No.: US 2026/0020225 A1
(43) Pub. Date: Jan. 15, 2026

(54) Storage Apparatus, Manufacturing Method Thereof, and Electronic Device

(71) Applicant: Huawei Technologies Co., Ltd., Shenzhen, (CN)

(72) Inventors: Guangfan Jiao, Shanghai (CN); Weiliang Jing, Shanghai (CN); Zhengbo Wang, Shenzhen (CN); HENG LIAO, Shanghai (CN)

(73) Assignee: Huawei Technologies Co., Ltd., Shenzhen, Guangdong (CN)

(21) Appl. No.: 19/337,486

(22) Filed: Sep. 23, 2025

Related U.S. Application Data
(63) Continuation of application No. PCT/CN2023/140242, filed on Dec. 20, 2023.

(30) Foreign Application Priority Data
Mar. 24, 2023 (CN) 202310352148.0

(51) Int. Cl. H10B 12/00

(52) U.S. Cl. CPC H10B 12/34; H10B 12/053

(57) ABSTRACT

This application relates to the field of storage technologies, and provides a storage apparatus, a manufacturing method thereof, and an electronic device, to resolve a row hammer (row hammer) problem of the storage apparatus. The storage apparatus includes a substrate having a plurality of active areas, a plurality of first trenches disposed in the active areas, and second trenches respectively disposed on two sides of the active area. In addition, in the storage apparatus, a plurality of memory cells are disposed in the active area, and the second trench is configured to isolate memory cells in two adjacent active areas. A first word line is disposed in the first trench, and the first word line is electrically connected to the memory cell. A second word line is disposed in the second trench.

### CROSS-REFERENCE TO RELATED APPLICATIONS

This application is a continuation of International Application No. PCT/CN2023/140242, filed on Dec. 20, 2023, which application claims priority to Chinese Patent Application No. 202310352148.0, filed on Mar. 24, 2023. The disclosures of the aforementioned applications are hereby incorporated by reference in their entireties.

### TECHNICAL FIELD

This application relates to the field of storage technologies, and in particular, to a storage apparatus, a manufacturing method thereof, and an electronic device.

### BACKGROUND

A dynamic random access memory (DRAM) is a type of semiconductor memory, and a main function principle is to use a quantity of charges stored in a capacitor to indicate that a binary bit (bit) is 1 or 0.

For example, as shown in FIG. 1, a DRAM includes a memory array including a plurality of memory cells 10. A word line WL is disposed in memory cells 10 corresponding to each row, and a bit line BL is disposed in memory cells 10 corresponding to each column. A transistor Tr and a capacitor Cap are disposed inside the memory cell 10, to control on/off of the transistor Tr through the word line WL and the bit line BL, thereby controlling charges stored in the capacitor Cap.

A row hammer effect is a security vulnerability problem in the DRAM, and causes mutual interference between memory cells 10 in adjacent rows, resulting in data damage. In an embodiment, refer to FIG. 1. When the DRAM frequently accesses memory cells 10 in a row (that is, an aggressor row, aggressor row) through the word line WL, capacitance in memory cells 10 in an adjacent row (that is, a victim row, victim row) changes. As a result, storage data is lost.

As a storage density of the DRAM continuously decreases, a word line pitch (WL pitch) in the memory array correspondingly continuously decreases. In this case, a storage charge loss caused by the row hammer effect of the DRAM becomes more serious. Especially, when the word line pitch decreases to less than 18 nm, the row hammer severely affects a retention feature of the DRAM.

### SUMMARY

This disclosure provides a storage apparatus, a manufacturing method thereof, and an electronic device, to resolve a row hammer problem of the storage apparatus.

This disclosure provides a storage apparatus. The storage apparatus includes a substrate having a plurality of active areas, a plurality of first trenches disposed in the active areas, and two second trenches respectively disposed on two sides of the active area. In addition, in the storage apparatus, a plurality of memory cells are disposed in the active area, and the second trench is configured to isolate memory cells in two adjacent active areas. A first word line electrically connected to the memory cell is disposed in the first trench, and a second word line is disposed in the second trench. In addition, in the storage apparatus, at least one isolation dielectric layer is disposed in the active area, and the isolation dielectric layer is spaced from the first word line, so that the isolation dielectric layer disposed in the active area can block a charge leakage tunnel generated by a word line (including the first word line and the second word line) in the active area. This reduces a quantity of charge leakage paths, thereby alleviating a row hammer problem.

In some possible implementations, there is a first distance between the bottom of the first word line and the bottom of the substrate, and there is a second distance between the bottom of the second word line and the bottom of the substrate; and the second distance is less than the first distance, that is, the bottom of the second word line is lower than the bottom of the first word line, or a depth of the second word line is greater than a depth of the first word line. In this case, a trap at the bottom of the second word line causes a large amount of charge leakage, and these charge leakage tunnels can be blocked by disposing the isolation dielectric layer, so that a quantity of charge leakage paths caused by the row hammer can be reduced, thereby alleviating the row hammer problem.

In some possible implementations, the storage apparatus includes a plurality of isolation dielectric layers; and an isolation dielectric layer is disposed between a second word line and a first word line that are adjacent to each other, and an isolation dielectric layer is disposed between two adjacent first word lines. Isolation dielectric layers are disposed between adjacent word lines, and the plurality of isolation dielectric layers can separately block charge leakage tunnels generated between two adjacent word lines, so that a quantity of charge leakage paths caused by the row hammer can be significantly reduced.

In some possible implementations, the isolation dielectric layer is in contact with the second word line, so that no trap exists in a contact area between the second word line and the isolation dielectric layer, thereby reducing charge leakage and alleviating the row hammer problem.

In some possible implementations, the bottom of the isolation dielectric layer is flush with the bottom of the second word line, so that there are fewer charge leakage paths caused by the row hammer in an area close to the bottom of the second word line, thereby alleviating the row hammer problem.

In some possible implementations, a distance between the bottom of the isolation dielectric layer and the bottom of the substrate is less than a distance between the bottom of the second word line and the bottom of the substrate, that is, the bottom of the isolation dielectric layer is lower than the bottom of the second word line, so that there are fewer charge leakage paths caused by the row hammer in an area close to the bottom of the second word line, thereby alleviating the row hammer problem.

In some possible implementations, the top of the isolation dielectric layer is higher than the bottom of the first word line, that is, a distance between the top of the isolation dielectric layer and the bottom of the substrate is greater than a distance between the bottom of the first word line and the bottom of the substrate, so that an effective length of a charge leakage tunnel in an area close to the first word line is reduced, thereby reducing a quantity of charge leakage paths caused by the row hammer.

In some possible implementations, the top of the isolation dielectric layer is flush with the top of the first word line, so that an effective length of a charge leakage tunnel in an area close to the first word line is further reduced, thereby significantly reducing a quantity of charge leakage paths caused by the row hammer.

In some possible implementations, the top of the isolation dielectric layer is higher than the top of the first word line, that is, a distance between the top of the isolation dielectric layer and the bottom of the substrate is greater than a distance between the top of the first word line and the bottom of the substrate, so that an effective length of a charge leakage tunnel in an area close to the first word line is further reduced, thereby significantly reducing a quantity of charge leakage paths caused by the row hammer.

In some possible implementations, the isolation dielectric layer includes at least one of SiO₂ or SiN.

In some possible implementations, the substrate includes a first substrate and a second substrate that are stacked, and the first trench is disposed in the first substrate, or the first trench extends from a surface of the first substrate to the second substrate. The second trench extends from the surface of the first substrate to the second substrate. A third trench is disposed on a side that is of the second substrate and that is close to the first substrate, and the isolation dielectric layer fills the third trench. The substrate is disposed as the first substrate and the second substrate that are stacked. In this case, the third trench is disposed on the surface of the first substrate (that is, a surface close to a side of the second substrate), and the isolation dielectric layer fills the third trench. In this way, the isolation dielectric layer is embedded into the active area of the substrate.

In some possible implementations, the first substrate is a Si substrate, and the second substrate is a Si epitaxial layer on a surface of the Si substrate.

This disclosure further provides a storage apparatus manufacturing method. The manufacturing method includes: providing a first substrate, where the first substrate includes a first semiconductor material, the first substrate has a plurality of active areas, and the plurality of active areas are used to manufacture a plurality of memory cells; manufacturing at least one third trench in the active area on a surface of the first substrate, and filling the third trench with a second semiconductor material; forming a second substrate on a side surface that is of the first substrate and on which the third trench is disposed; and then removing the second semiconductor material that fills the third trench, and refilling the third trench with a dielectric material to form an isolation dielectric layer; forming a plurality of first trenches in the active area on a surface of the second substrate, and respectively forming second trenches on two sides of the active area on the surface of the second substrate, where the first trench is spaced from the isolation dielectric layer, the second trench extends to the first substrate, and a depth of the second trench is greater than a depth of the first trench; and forming a first word line in the first trench, and forming a second word line in the second trench.

In some possible implementations, the forming the second substrate on the side surface that is of the first substrate and on which the third trench is disposed includes: growing an epitaxial layer on the side surface that is of the first substrate and on which the third trench is disposed.

In some possible implementations, the forming the plurality of first trenches in the active area on the surface of the second substrate includes: forming, in the active area on the surface of the second substrate, the plurality of first trenches extending to the first substrate.

In some possible implementations, the respectively forming the second trenches on the two sides of the active area on the surface of the second substrate includes: respectively forming the second trenches on the two sides of the active area on the surface of the second substrate, and exposing the isolation dielectric layer on a side surface of the second trench; and the forming the second word line in the second trench includes: forming, in the second trench, the second word line in contact with the isolation dielectric layer.

This disclosure further provides an electronic device. The electronic device includes a circuit board and the storage apparatus provided in any one of the foregoing possible implementations, and the storage apparatus is electrically connected to the circuit board.

### BRIEF DESCRIPTION OF DRAWINGS

FIG. 1 is a diagram of a memory array of a storage apparatus in the conventional technology;

FIG. 2 is a plane diagram of a storage apparatus according to an embodiment of this disclosure;

FIG. 3 is a cross-sectional diagram of FIG. 2 along a position XX′;

FIG. 4 is a partial cross-sectional diagram of a storage apparatus according to a related technology of this disclosure;

FIG. 5 is a partial cross-sectional diagram of a storage apparatus according to an embodiment of this disclosure;

FIG. 6 is a partial cross-sectional diagram of a storage apparatus according to an embodiment of this disclosure;

FIG. 7 is a partial cross-sectional diagram of a storage apparatus according to an embodiment of this disclosure;

FIG. 8 is a flowchart of a storage apparatus manufacturing method according to an embodiment of this disclosure;

FIG. 9 is a diagram of a storage apparatus manufacturing process according to an embodiment of this disclosure;

FIG. 10 is a diagram of a storage apparatus manufacturing process according to an embodiment of this disclosure;

FIG. 11 is a diagram of a storage apparatus manufacturing process according to an embodiment of this disclosure;

FIG. 12 is a diagram of a storage apparatus manufacturing process according to an embodiment of this disclosure; and

FIG. 13 is a diagram of a storage apparatus manufacturing process according to an embodiment of this disclosure.

### DESCRIPTION OF EMBODIMENTS

To make objectives, technical solutions, and advantages of this disclosure clearer, the following clearly and completely describes the technical solutions in this disclosure with reference to accompanying drawings in this disclosure. It is clear that the described embodiments are some but not all of embodiments of this disclosure. All other embodiments obtained by a person of ordinary skill in the art based on embodiments of this disclosure without creative efforts shall fall within the protection scope of this disclosure.

In the specification, embodiments, claims, and accompanying drawings of this disclosure, terms such as “first” and “second” are merely used for differentiation and description, but should not be understood as an indication or implication of relative importance or an indication or implication of a sequence. The term “and/or” is used for describing an association relationship between associated objects, and represents that three relationships may exist. For example, “A and/or B” may represent the following three cases: Only A exists, only B exists, and both A and B exist, where A and B may be singular or plural. The character “/” usually represents an “or” relationship between associated objects. “At least one piece (item)” means one or more, and “a plurality of” means two or more. “Mounting”, “connection”, “interconnection”, and the like should be understood in a broad sense, for example, may be an electrical connection or a mechanical connection; may be a fixed connection, a detachable connection, or an integrated connection; or may be a direct connection, an indirect connection through an intermediate medium, or communication between interiors of two elements. In addition, the terms “include”, “have”, and any variant thereof are intended to cover non-exclusive inclusion. For example, a process, method, system, product, or device that includes a list of steps or units is not necessarily limited to those expressly listed steps or units, but may include other steps or units not expressly listed or inherent to such a process, method, system, product, or device. “Up”, “down”, “left”, “right”, “high”, “low”, and the like are used only relative to orientations of components in the accompanying drawings. These directional terms are relative concepts, and are used for relative description and clarification, and may change correspondingly based on changes in placement orientations of the components in the accompanying drawings.

Embodiments of this disclosure provides an electronic device. The electronic device includes a circuit board (printed circuit board, PCB, which may also be referred to as a printed circuit board) and a storage apparatus electrically connected to the circuit board. The storage apparatus uses a new structure in which an isolation dielectric layer is embedded into an active area of a substrate, to block a charge leakage tunnel generated by a word line, thereby alleviating a row hammer problem.

A disposing form of the electronic device is not limited in this disclosure. For example, the electronic device may be an electronic product or a component such as a mobile phone, a tablet computer, a notebook computer, a vehicle-mounted computer, a smartwatch, a smart band, or a server.

A disposing form of the storage apparatus is not limited in this disclosure. The electronic component may be any device or component having a storage function. For example, in some possible implementations, the storage apparatus may be a memory (for example, a DRAM), a CPU (central processing unit, central processing unit), an SOC (system on chip, system on chip), or the like.

The following describes a structure of the storage apparatus provided in embodiments of this disclosure.

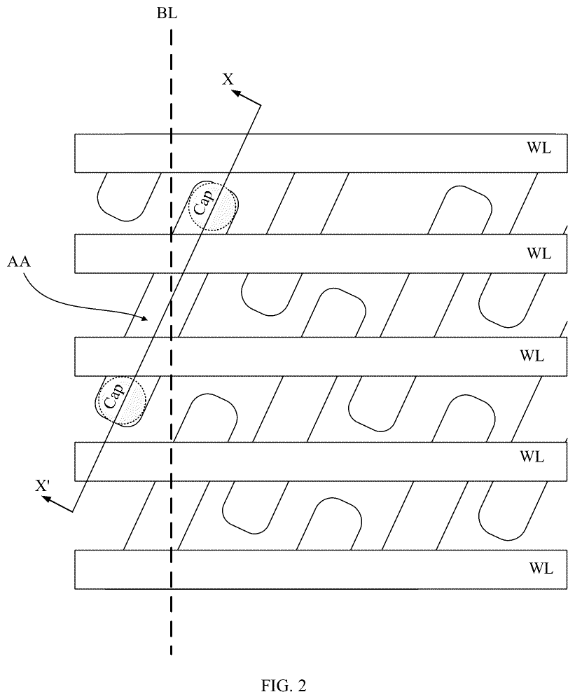

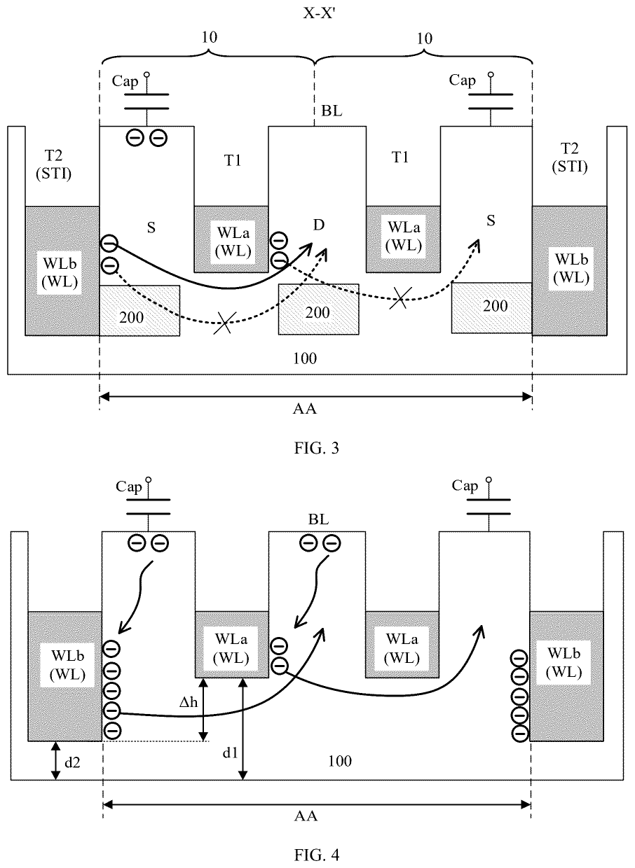

FIG. 2 is a plane diagram of a storage apparatus according to an embodiment of this disclosure. FIG. 3 is a cross-sectional diagram of FIG. 2 along XX′.

An embodiment of this disclosure provides a storage apparatus. With reference to FIG. 2 and FIG. 3, the storage apparatus includes a substrate 100, a plurality of active areas AA (active area) are disposed on the substrate 100, and there is an isolation area between adjacent active areas AA. For example, the substrate 100 may be a Si substrate, but this is not limited thereto.

With reference to FIG. 2 and FIG. 3, on the substrate 100, a plurality of first trenches T1 are disposed in the active area AA, and one second trench T2 is disposed in each of isolation areas on two sides of the active area AA. A depth of the second trench T2 is greater than a depth of the first trench T1, that is, there is a specific height difference between the bottom of the second trench T2 and the bottom of the first trench T1. A first word line WLa is disposed in the first trench T1, and a second word line WLb is disposed in the second trench T2. In FIG. 3, only an example in which two first word lines WLa are disposed in the active area AA is used for description. However, this disclosure is not limited thereto.

It may be understood that, with reference to FIG. 2 and FIG. 3, a plurality of word lines WL are disposed in parallel on the substrate 100. A single word line WL uses a segmented structure, a partial area of the word line WL is the first word line WLa, and a partial area of the word line WL is the second word line WLb. In an embodiment, a part that is of the word line WL and that is located in the active area AA is disposed in the first trench T1, that is, the first word line WLa, and a part that is of the word line WL and that is located in an isolation area (that is, an area between active areas AA) is disposed in the second trench T2, that is, the second word line WLb.

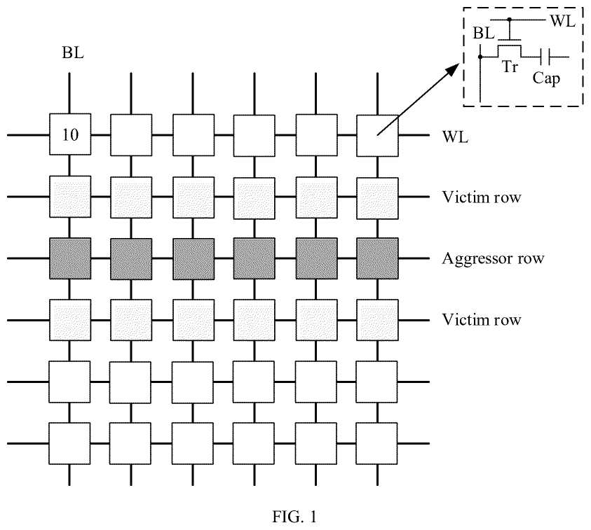

With reference to FIG. 1, FIG. 2, and FIG. 3, a plurality of memory cells 10 are disposed in the storage apparatus, the plurality of memory cells 10 are distributed in the plurality of active areas AA, and memory cells 10 in adjacent active areas AA can be isolated by disposing the second trench T2, that is, shallow trench isolation STI (shallow trench isolation), to ensure that the memory cells 10 in the active areas AA operate independently. For specific settings of a transistor Tr and a capacitor Cap in the memory cell 10, refer to the following related descriptions.

To clearly and briefly describe inventive points of this disclosure, the following embodiments are described by using a single active area AA and isolation areas on two sides of the active area AA as a unit structure.

It should be understood that, referring to FIG. 2 and FIG. 3, in the active area AA, a source region S and a drain region D that are of a transistor (refer to Tr in FIG. 1) are formed in areas on two sides of the first word line WLa, and when the transistor is turned on, a conductive channel is formed between the source region S and the drain region D and in an area surrounding the first word line WLa. In other words, in the active area AA, each first word line WLa is correspondingly electrically connected to a transistor in one memory cell 10. A capacitor Cap in the memory cell 10 may be disposed above the active area AA of the substrate.

For example, the active areas AA shown in FIG. 2 and FIG. 3 each have two first word lines WLa, which are respectively correspondingly connected to transistors in two memory cells. An area between the two first word lines WLa is a same drain region D. This is equivalent to that the two transistors share the same drain region D. In this case, capacitors Cap in the two memory cells 10 are respectively disposed above two source regions S, and a corresponding bit line BL in the storage apparatus may be disposed above the shared drain region D.

Refer to FIG. 4. Because a trap exists in an interface between a word line WL (including WLa and WLb) and the substrate 100 (for example, the Si substrate), when the word line WL is at a high potential and the transistor is turned on, electrons in the capacitor Cap and the bit line BL are attracted to the word line WL, and some electrons are captured by the trap in the interface between the word line WL and the substrate 100. When a voltage on the word line WL is reset and the transistor is turned off, the electrons captured by the trap escape (leak) to an adjacent memory cell, causing interference. Consequently, data is lost, that is, a row hammer problem occurs.

For example, refer to FIG. 4. In some possible implementations, the bottom of the second word line WLb is lower than the bottom of the first word line WLa, that is, a distance d2 (a second distance) from the bottom of the second word line WLb to the bottom of the substrate 100 is less than a distance d1 (a first distance) from the bottom of the first word line WLa to the bottom of the substrate 100, and d2<d1. In this case, there is a height difference Δh between the bottom of the second word line WLb and the bottom of the first word line WLa, and a trap at the bottom of the second word line WLa causes a large amount of charge leakage. As a result, the row hammer problem deteriorates.

Based on this, to alleviate a charge leakage problem caused by the row hammer, as shown in FIG. 3, in the storage apparatus provided in this embodiment of this disclosure, at least one isolation dielectric layer 200 is disposed in an active area AA located between two second word lines WLb, and the isolation dielectric layer 200 can block a charge leakage tunnel generated by the word lines (WLa and WLb) in the active area AA. This reduces a quantity of charge leakage paths, thereby alleviating the row hammer problem.

Especially when the bottom of the second word line WLb is lower than the bottom of the first word line WLa, a trap at the bottom of the second word line causes a large amount of charge leakage. A quantity of charge leakage paths generated at the bottom of the second word line can be reduced by disposing the isolation dielectric layer, thereby better alleviating the row hammer problem.

For example, it can be learned by comparing FIG. 3 and FIG. 4 that, when the isolation dielectric layer 200 is not disposed, a length of a charge leakage tunnel (tunnel length) is L, and after the isolation dielectric layer 200 is disposed, an effective length of the charge leakage tunnel caused by the row hammer is L_{eff}=L−ΔL. In other words, a charge leakage path that exists when the isolation dielectric layer 200 is not disposed is blocked (dashed arrow) by the disposed isolation dielectric layer 200.

It should be understood herein that, when the transistor in the memory cell 10 is turned on, a channel is formed between the source region S and the drain region D and in the area surrounding the first word line WLa. Therefore, to ensure normal operation of the memory cell, a specific spacing needs to be reserved between the isolation dielectric layer 200 and the first word line WLa, to avoid impact on the conductive channel of the transistor.

A specific material used by the isolation dielectric layer 200 is not limited in this disclosure, and may be selected and set based on a requirement in practice. For example, in some possible implementations, the isolation dielectric layer 200 may use one or more of dielectric materials such as SiO₂ and SiN.

A quantity of isolation dielectric layers 200 disposed in the single active area AA is not limited in this disclosure. One isolation dielectric layer 200 or a plurality of isolation dielectric layers 200 may be disposed in one active area AA in practice based on a requirement.

For example, in some possible implementations, as shown in FIG. 3, an isolation dielectric layer 200 may be disposed between two adjacent word lines WL. To be specific, an isolation dielectric layer 200 is disposed between the first word line WLa and the second word line WLb that are adjacent to each other, and an isolation dielectric layer 200 is disposed between two adjacent first word lines WLa. In this way, charge leakage tunnels generated between two adjacent word lines can be separately blocked by a plurality of isolation dielectric layers, thereby significantly reducing a quantity of charge leakage paths caused by the row hammer. For example, in some embodiments, an isolation dielectric layer 200 may be disposed in the middle of two word lines WL.

For another example, in some possible implementations, an isolation dielectric layer 200 may be disposed, and the isolation dielectric layer 200 may extend to cover most of the active area AA. For example, one end of the isolation dielectric layer 200 may be in contact with a side surface of a second word line WLb located on the left side of the active area AA, and the other end of the isolation dielectric layer 200 may be in contact with a side surface of a second word line WLb located on the right side of the active area AA.

In addition, in practice, a shape, a size, a specific position, and the like of the isolation dielectric layer 200 may be set based on a requirement such as an disclosure scenario.

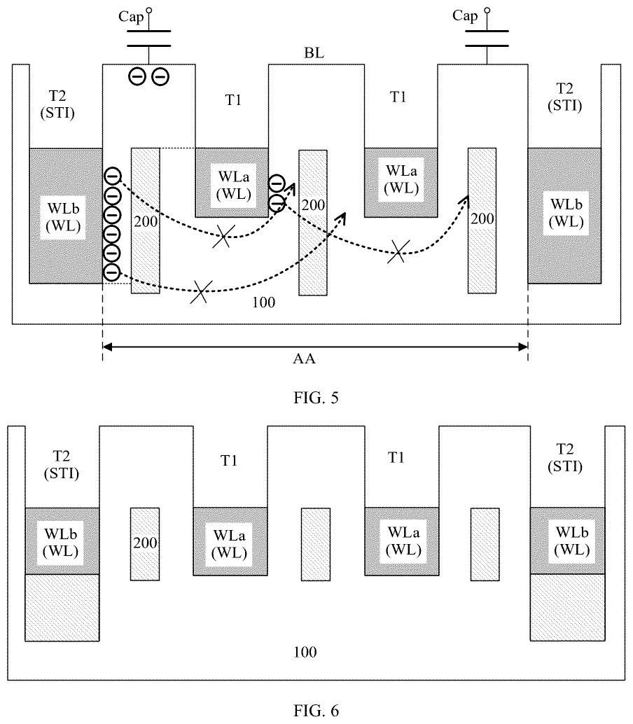

For example, in some possible implementations, as shown in FIG. 3 and FIG. 5, the isolation dielectric layer 200 may be in a shape of a square block, a strip, or the like.

For example, in some possible implementations, as shown in FIG. 3, a side surface that is of the second word line WLb and that is close to the bottom of the active area AA may be set to be in contact with the isolation dielectric layer 200, so that no trap exists in a contact area between the second word line WLb and the isolation dielectric layer 200. In this way, charge leakage is reduced, and the row hammer problem is alleviated.

It may be understood herein that, because the second word line WLb is located in an isolation area on a side surface of the active area AA, no conductive channel needs to be formed around the second word line WLb, and disposing the isolation dielectric layer 200 to be in contact with the second word line WLb does not adversely affect the component.

In addition, to significantly reduce charge leakage caused by the trap at the bottom of the second word line WLb, the isolation dielectric layer 200 may be extended to a depth below the second word line WLb. This may be set as required in practice.

For example, in some possible implementations, as shown in FIG. 3, when the isolation dielectric layer 200 is in contact with the side surface of the second word line WLb, the bottom of the isolation dielectric layer 200 may be set to be flush with the bottom of the second word line WLb, so that a charge leakage path caused by the trap at the bottom of the second word line WLb can be significantly blocked.

For another example, in some possible implementations, as shown in FIG. 5, when the isolation dielectric layer 200 is spaced from the second word line WLb, the bottom of the isolation dielectric layer 200 may be set to be lower than the bottom of the second word line WLb, so that a charge leakage path caused by the trap at the bottom of the second word line WLb can be significantly blocked.

Similarly, to significantly block a charge leakage path generated around the first word line WLa, the top of the isolation dielectric layer 200 may be set to extend above the bottom of the first word line WLa, or the bottom of the first word line WLa extends below the isolation dielectric layer 200, that is, a distance between the top of the isolation dielectric layer 200 and the bottom of the substrate 100 is greater than a distance between the bottom of the first word line WLa and the bottom of the substrate 100. In this way, an effective length of a charge leakage tunnel in an area close to the bottom of the first word line WLa is reduced, thereby reducing a quantity of charge leakage paths caused by the row hammer.

For example, in some possible implementations, as shown in FIG. 5, the top of the isolation dielectric layer 200 may be set to be flush with the top of the first word line WLa, so that an effective length of a charge leakage tunnel in an area close to the first word line WLa is further reduced, thereby significantly reducing a quantity of charge leakage paths caused by the row hammer.

For another example, in some possible implementations, the top of the isolation dielectric layer 200 may be set to be higher than the top of the first word line WLa, that is, a distance between the top of the isolation dielectric layer 200 and the bottom of the substrate 100 is greater than a distance between the top of the first word line and the bottom of the substrate 100, so that an effective length of a charge leakage tunnel in an area close to the first word line WLa is further reduced, thereby significantly reducing a quantity of charge leakage paths caused by the row hammer.

Certainly, based on an actual requirement, the top of the second word line WLb may be flush with or approximately flush with the top of the first word line WLa. This is not limited in this disclosure.

It should be noted herein that the foregoing embodiments are described by using an example in which the bottom of the second word line WLb is lower than the bottom of the first word line WLa. However, this disclosure is not limited thereto. In some embodiments, when the bottom of the second word line WLb is flush with the bottom of the first word line WLa, a quantity of charge leakage tunnels caused by the row hammer can also be reduced by disposing the isolation dielectric layer 200.

For example, as shown in FIG. 6, in some possible implementations, the bottom of the second trench T2 may be filled with a dielectric material, to ensure that the bottom of the second word line WLb is flush with the bottom of the first word line WLa. In this case, the isolation dielectric layer 200 is disposed between two adjacent word lines WL in the active area AA, so that a charge leakage path generated by the word lines (WLa and WLb) can be further blocked, thereby significantly alleviating the row hammer problem.

In addition, a specific manufacturing form of the isolation dielectric layer 200 is not limited in this disclosure. In practice, a proper process may be selected based on a requirement for manufacturing.

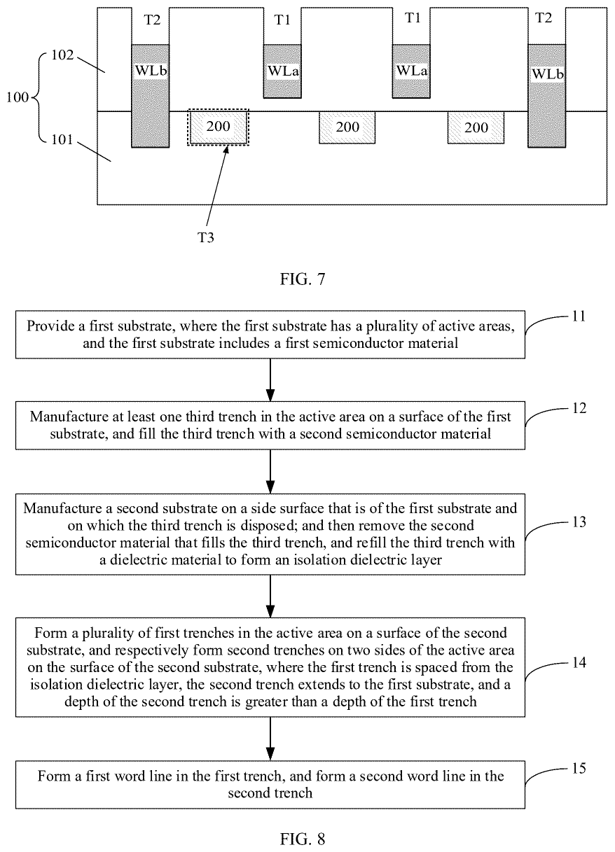

For example, in some possible implementations, as shown in FIG. 7, the substrate 100 may be disposed as a first substrate 101 and a second substrate 102 that are stacked. For example, the first substrate 101 may be a Si wafer, and the second substrate 102 may be a Si epitaxial layer on a surface of the Si wafer.

On this basis, as shown in FIG. 7, a third trench T3 may be disposed on an upper surface (that is, a surface close to a side of the second substrate 102) of the first substrate 101, and the third trench T3 is filled with the isolation dielectric layer 200.

As shown in FIG. 7, in some possible implementations, the first trench T1 provided with the first word line WLa may be disposed in the second substrate 102. In this case, the first word line WLa is embedded into the second substrate 102. In some other possible implementations, the first trench T1 may alternatively extend from an upper surface of the second substrate 102 (that is, a surface on a side away from the first substrate 101) to the first substrate 101. In this case, the first word line WLa may be embedded into the first substrate 101.

As shown in FIG. 7, the second trench T2 provided with the second word line WLb may be set to extend from the upper surface of the second substrate 102 to the second substrate 102. In this case, the second word line WLb may be embedded into the first substrate 101, or may be embedded into the first substrate 101 and the second substrate 102.

The following further describes the storage apparatus provided in this embodiment of this disclosure with reference to a specific manufacturing method.

For example, an embodiment of this disclosure provides a storage apparatus manufacturing method. As shown in FIG. 8, the manufacturing method may include the following steps:

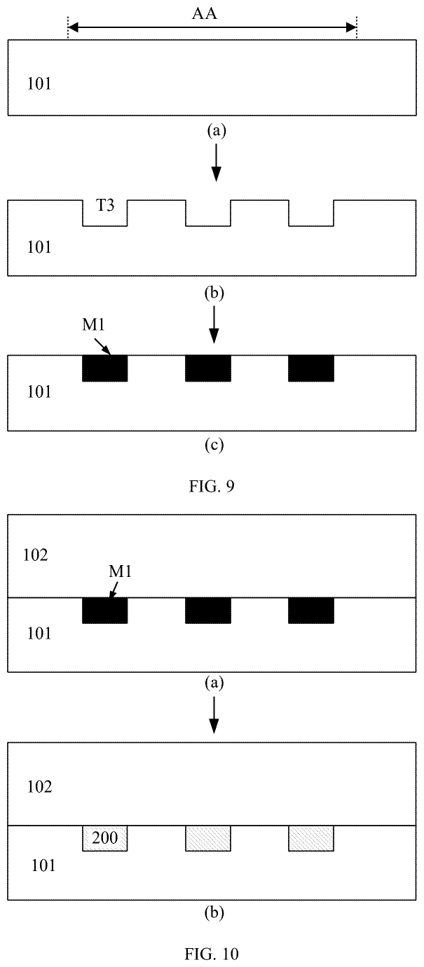

Step 11: As shown in (a) in FIG. 9, provide a first substrate 101, where the first substrate 101 has a plurality of active areas AA (FIG. 9 shows only one active area), and the first substrate 101 includes a first semiconductor material.

Positions of the plurality of active areas AA are pre-designed and defined on the first substrate 101 based on an actual requirement, and are used to subsequently manufacture a plurality of memory cells 10 in the plurality of active areas AA. For details, refer to the foregoing related descriptions.

For example, in some possible implementations, step 11 may include: providing a Si substrate (101), for example, a Si wafer.

Step 12: As shown in (b) and (c) in FIG. 9, manufacture at least one third trench T3 in the active area AA on a surface of the first substrate 101, and fill the third trench T3 with a second semiconductor material M1.

The second semiconductor material M1 and the first semiconductor material in the first substrate 101 are two different semiconductor materials.

For example, in some possible implementations, step 12 may include: as shown in (b) in FIG. 9, manufacturing a plurality of third trenches T3 in the active area AA on a surface of the Si wafer (101) by using an etching process; and then, as shown in (c) in FIG. 9, filling the third trenches T3 by depositing SiGe (M1).

Step 13: As shown in (a) and (b) in FIG. 10, manufacture a second substrate 102 on a side surface that is of the first substrate 101 and on which the third trench T3 is disposed; and then remove the second semiconductor material M1 filling the third trench T3, and refill the third trench T3 with a dielectric material to form an isolation dielectric layer 200.

For example, in some possible implementations, step 13 may include: as shown in (a) and (b) in FIG. 10, growing a Si epitaxial layer (102) on the surface of the Si wafer (101) by using an epitaxial growth process; and then removing SiGe (M1) filling the third trench T3 through etching (for example, wet etching), and filling the third trench T3 with the dielectric material (such as SiO₂ or SiN) by using an atomic layer deposition (atomic layer deposition, ALD) process, to form the isolation dielectric layer 200.

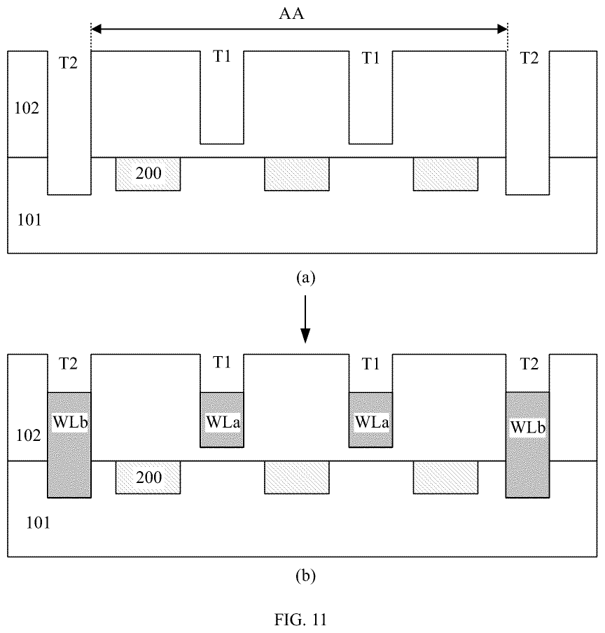

Step 14: As shown in (a) in FIG. 11, form a plurality of first trenches T1 in the active area AA on a surface of the second substrate 102, and respectively form second trenches T2 on two sides of the active area AA on the surface of the second substrate 102, where the first trench T1 is spaced from the isolation dielectric layer 200, the second trench T2 extends to the first substrate 101, and a depth of the second trench T2 is greater than a depth of the first trench T1.

For example, in some possible implementations, step 14 may include: as shown in (a) in FIG. 11, forming the plurality of first trenches T1 in the active area AA on a surface of the Si epitaxial layer (102) by using an etching process, where the first trench T1 may be located in the Si epitaxial layer (102); and forming, in isolation areas on the two sides of the active area AA, the second trenches T2 that extend to the Si wafer (101).

Step 15: As shown in (b) in FIG. 11, form a first word line WLa in the first trench T1, and form a second word line WLb in the second trench T2.

For example, in some possible implementations, step 15 may include: as shown in (b) in FIG. 11, forming the first word line WLa in the first trench T1 by using a metal deposition process, and forming the second word line WLb in the second trench T2 by using the metal deposition process.

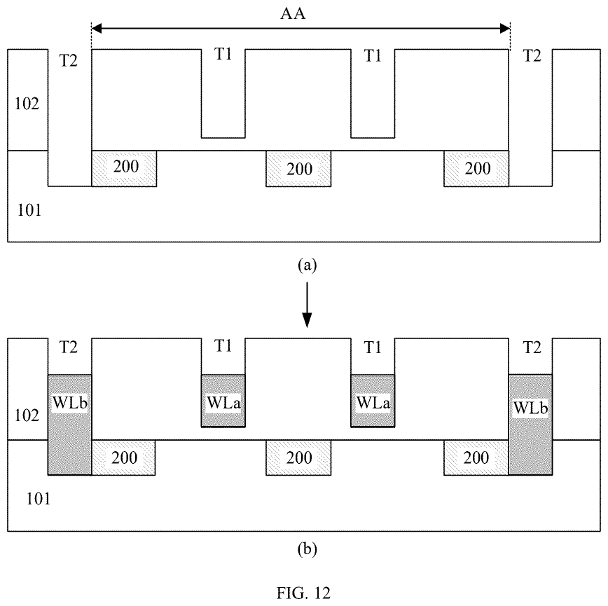

In another possible implementation, as shown in (a) in FIG. 12, when the second trench T2 is formed by using step 14, the isolation dielectric layer 200 may be exposed on a side surface of the second trench T2. In this case, as shown in (b) in FIG. 12, the second word line WLb in contact with the isolation dielectric layer 200 can be formed in the second trench T2 by using step 15. In this way, no trap exists in a contact area between the second word line and the isolation dielectric layer, so that charge leakage is reduced, and the row hammer problem is alleviated. For details, refer to the foregoing related descriptions.

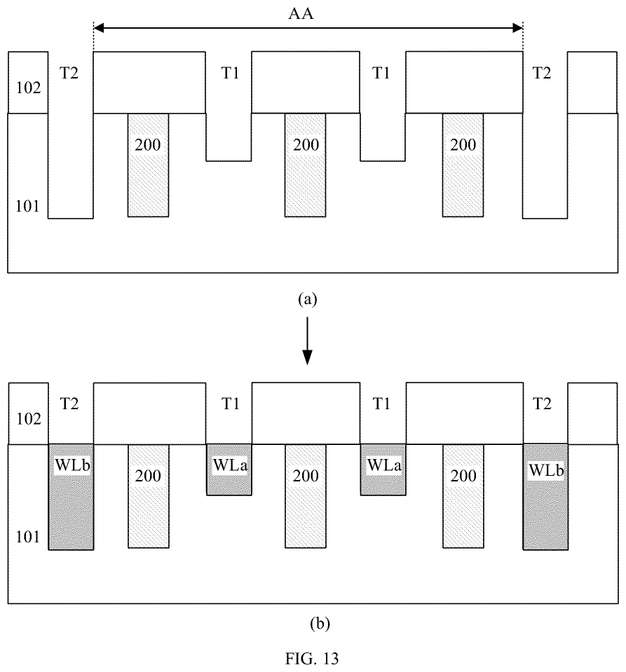

In another possible implementation, as shown in (a) in FIG. 13, when the first trench T1 is formed by using step 14, the first trench T1 may extend to the first substrate 101. In this case, as shown in (b) in FIG. 13, the first word line WLa formed by using step 15 may be directly embedded into the first substrate 101. In this way, the bottom of the first word line WLa may extend below the isolation dielectric layer 200, thereby reducing an effective length of a charge leakage tunnel in an area close to the bottom of the first word line WLa, and further reducing a quantity of charge leakage paths caused by the row hammer. For details, refer to the foregoing related descriptions.

In addition, as shown in FIG. 11, when the first trench T1 is disposed in the Si epitaxial layer (102), the first word line WLa is embedded into the Si epitaxial layer (102), and it needs to be ensured that the Si epitaxial layer (102) has a sufficient thickness, to meet a manufacturing requirement of the first word line WLa.

In contrast, as shown in FIG. 13, when the first trench T1 extends to the Si wafer (101), the first word line WLa may be embedded into the Si wafer (101), to reduce a thickness of the Si epitaxial layer (102). In addition, the bottom of the first word line WLa is lower than the top of the isolation dielectric layer 200. This helps block a charge leakage path generated by word lines (WLa and WLb), thereby significantly alleviating the row hammer problem.

For a specific shape, a position, and the like of the isolation dielectric layer 200, refer to the foregoing embodiments, and the isolation dielectric layer 200 may be correspondingly manufactured with reference to the foregoing related manufacturing process. Details are not described herein again.

It should be understood that, in various embodiments of this disclosure, sequence numbers of the foregoing manufacturing processes do not mean execution sequences. The execution sequences of the manufacturing processes should be determined based on specific functions and internal logic of the components, and should not be construed as any limitation on the implementation processes of embodiments of this disclosure.

In addition, for other related content in the foregoing manufacturing method, correspondingly refer to a corresponding part in the structure embodiment of the foregoing storage apparatus. Details are not described herein again. For another disposing structure of the foregoing storage apparatus, refer to the foregoing manufacturing method and a related manufacturing method for adjustment. Details are not described herein again.

The foregoing descriptions are merely specific implementations of this disclosure, but are not intended to limit the protection scope of this disclosure. Any variation or replacement readily figured out by a person skilled in the art within the technical scope disclosed in this disclosure shall fall within the protection scope of this disclosure. Therefore, the protection scope of this disclosure shall be subject to the protection scope of the claims.

What is claimed is:

1. A storage apparatus, comprising:
a plurality of memory cells;
a substrate, wherein the substrate has a plurality of active areas, and the memory cells are disposed in the active areas;
a plurality of first trenches disposed in the active areas, wherein a first word line is disposed in each first trench, and the first word line is electrically connected to the memory cell;
second trenches disposed on two sides of the active area, wherein the second trench is configured to isolate memory cells in two adjacent active areas, and a second word line is disposed in each second trench; and
at least one isolation dielectric layer, wherein the at least one isolation dielectric layer is located in the active area, and the isolation dielectric layer is spaced from the first word line.

2. The storage apparatus according to claim 1, wherein there is a first distance between a bottom of the first word line and a bottom of the substrate, and there is a second distance between a bottom of the second word line and the bottom of the substrate; and the second distance is less than the first distance.

3. The storage apparatus according to claim 1, wherein the storage apparatus comprises a plurality of isolation dielectric layers; and an isolation dielectric layer is disposed between a second word line and a first word line that are adjacent to each other, and an isolation dielectric layer is disposed between two adjacent first word lines.

4. The storage apparatus according to claim 1, wherein the isolation dielectric layer is in contact with the second word line.

5. The storage apparatus according to claim 1, wherein a bottom of the isolation dielectric layer is flush with the bottom of the second word line; or a distance between the bottom of the isolation dielectric layer and the bottom of the substrate is less than the distance between the bottom of the second word line and the bottom of the substrate.

6. The storage apparatus according to claim 1, wherein a top of the isolation dielectric layer is higher than the bottom of the first word line.

7. The storage apparatus according to claim 1, wherein the top of the isolation dielectric layer is flush with a top of the first word line; or the top of the isolation dielectric layer is higher than a top of the first word line.

8. The storage apparatus according to claim 1, wherein the isolation dielectric layer comprises at least one of SiO₂ or SiN.

9. The storage apparatus according to claim 1, wherein the substrate comprises a first substrate and a second substrate that are stacked; the first trench is disposed in the first substrate; or the first trench extends from a surface of the first substrate to the second substrate; the second trench extends from the surface of the first substrate to the second substrate; and a third trench is disposed on a side that is of the second substrate and that is close to the first substrate, and the isolation dielectric layer fills the third trench.

10. The storage apparatus according to claim 9, wherein the first substrate is a Si substrate, and the second substrate is a Si epitaxial layer on a surface of the Si substrate.

11. A storage apparatus manufacturing method, comprising:
providing a first substrate, wherein the first substrate comprises a first semiconductor material, the first substrate has a plurality of active areas, and the plurality of active areas are used to manufacture a plurality of memory cells;
manufacturing at least one third trench in the active area on a surface of the first substrate, and filling the third trench with a second semiconductor material;
forming a second substrate on a side surface that is of the first substrate and on which the third trench is disposed; and then removing the second semiconductor material that fills the third trench, and refilling the third trench with a dielectric material to form an isolation dielectric layer;
forming a plurality of first trenches in the active area on a surface of the second substrate, and respectively forming second trenches on two sides of the active area on the surface of the second substrate, wherein the first trench is spaced from the isolation dielectric layer, the second trench extends to the first substrate, and a depth of the second trench is greater than a depth of the first trench; and
forming a first word line in the first trench, and forming a second word line in the second trench.

12. The storage apparatus manufacturing method according to claim 11, wherein the forming the plurality of first trenches in the active area on the surface of the second substrate comprises: forming, in the active area on the surface of the second substrate, the plurality of first trenches extending to the first substrate.

13. The storage apparatus manufacturing method according to claim 11, wherein the respectively forming the second trenches on the two sides of the active area on the surface of the second substrate comprises: respectively forming the second trenches on the two sides of the active area on the surface of the second substrate, and exposing the isolation dielectric layer on a side surface of the second trench; and the forming the second word line in the second trench comprises: forming, in the second trench, the second word line in contact with the isolation dielectric layer.

14. An electronic device, comprising a circuit board and the storage apparatus, wherein the storage apparatus comprises:
a plurality of memory cells;
a substrate, wherein the substrate has a plurality of active areas, and the memory cells are disposed in the active areas;
a plurality of first trenches disposed in the active areas, wherein a first word line is disposed in each first trench, and the first word line is electrically connected to the memory cell;
second trenches disposed on two sides of the active area, wherein the second trench is configured to isolate memory cells in two adjacent active areas, and a second word line is disposed in each second trench; and
at least one isolation dielectric layer, wherein the at least one isolation dielectric layer is located in the active area, and the isolation dielectric layer is spaced from the first word line; and wherein the storage apparatus is electrically connected to the circuit board.
